(19) United States
(12) Patent Application Publication
(10) Pub. No.: US 2009/0322184 A1
(43) Pub. Date: Dec. 31, 2009

(54) Energy Harvesting Using Frequency Rectification

(76) Inventors: Gregory P Carman, Los Angeles, CA (US); Dong Gun Lee, Los Angeles, CA (US)

Correspondence Address: VENABLE LLP, P.O. BOX 34385, WASHINGTON, DC, 20043-9998, US

(21) Appl. No.: 11/992,424

(22) PCT Filed: Sep. 21, 2006
(86) PCT No.: PCT/US2006/036708

§ 371 Date: Jul. 31, 2009

Related U.S. Application Data
(60) Provisional application No. 60/719,565, filed on Sep. 23, 2005.

(51) Int. Cl. H01L 41/113

(52) U.S. Cl. 310/339

(57) ABSTRACT

An energy harvesting apparatus includes an inverse frequency rectifier structured to receive mechanical energy at a first frequency, and a solid state electromechanical transducer coupled to the inverse frequency rectifier t receive a force provided by the inverse frequency rectifier. The force, when provided by the inverse frequency rectifier, causes the solid state transducer to be subjected to a second frequency that is higher than the first frequency to thereby generate electrical power.

### FIELD OF THE INVENTION

Embodiments of the present invention relate to vibration energy harvesting (or energy scavenging) techniques using an electroactive generator, and an energy rectifier, more particularly, a mechanical frequency rectifier converting low-frequency ambient vibrations into high frequency vibrations.

### BACKGROUND OF THE INVENTION

Energy harvesting (or energy scavenging) is defined as the conversion of ambient mechanical energy, for example, but not limited to, vibrational energy, into usable electrical energy. The electrical energy harvested can then be used as a power source for a variety of low-power applications, such as, but not limited to, remote applications that may involve networked systems of wireless sensors and/or communication nodes, where other power sources such as batteries may be impractical [J. A. Paradiso, T. Starner, IEEE Pervasive Computing, January-March 18-27 (2005); S. Roundy, E. S. Leland, J. Baker, E. Carleton, E. Reilly, E. Lai, B. Otis, J. M. Rabacy, P. K. Wright, IEEE Pervasive Computing, January-March:28-35 (2005)]. For these reasons, the amount of research devoted to power harvesting has been rapidly increasing [H. A. Sodano, D. J. Inman, G. Park, The Shook and Vibration Digest, Vol. 36: 197-205 (2004)].

Vibration-based energy harvesters have been successfully developed using, for example, electromagnetic, electrostatic, and piezoelectric methods of electromechanical generation [S. Roundy, E. S. Leland, J. Baker, E. Carleton, E. Reilly, E. Lai, B. Otis, J. M. Rabacy, P. K. Wright, IEEE Pervasive Computing, January-March: 28-35 (2005)]. A piezoelectric harvester has gained considerable attention because piezoelectric energy conversion produces relatively higher voltage than other electromechanical generators. A piezoelectric harvester can convert mechanical energy into electrical energy by straining a piezoelectric material that then uses atomic deformations to change the polarization of the material and to produce net voltage changes. The net voltage can be scavenged and converted into stored power in either a battery or a capacitor, or it may be used as it is being created.

The amount of power accumulated via the piezoelectric harvester (or generator) is proportional to the mechanical frequency which is exciting it [H. W. Kim, A. Batra, S. Priya, K. Uchino, D. Markley, R. E. Newnham, H. F. Hofmann, The Japan Society of Applied Physics, Vol. 43 9A:6178-6183 (2004)]. In most non-resonant energy generators, the mechanical frequency input to the generator (e.g., piezoelectric material) corresponds to the environment's dominant mechanical frequency, which in most all cases is relatively low (i.e., below 100 Hz). For example, a heel-strike power harvester [N. S. Shenck, J. A. Paradiso, IEEE Micro, Vol. 21:30-41 (2001)], disclosed in U.S. Pat. No. 6,433,465 B1 (Mcknight et al.), harvests energy from a walking motion that occurs at approximately 1 Hz. The frequency of this generator matches the driving frequency of the heel strike. This low frequency generator limits the amount of electromechanical power that can be converted. As a result, the power harvested via the non-resonant generator is insufficient to power most electronic-based systems. Therefore, a relatively small non-resonant generator may, typically, not be able to generate sufficient power due to the low-frequency ambient vibrations.

On the other hand, a resonant piezoelectric generator is disclosed in U.S. Pat. No. 3,456,134 (Ko et al.), U.S. Pat. No. 4,900,970 (Ando et al.) and U.S. Pat. No. 6,858,870 B2 (Malkin et al.). For the resonant vibration-based generators, the harvesting power can be maximized when the resonance frequency matches the driving frequency of the ambient vibration source [J. A. Paradiso, T. Starner, IEEE Pervasive Computing, January-March: 18-27 (2005)]. Otherwise, the harvesting power output drops off dramatically as resonance frequency deviates from the driving frequency. To harvest maximum energy, the piezoelectric generator in such systems is designed to exploit the oscillation of a proof mass resonantly tuned to the environment's dominant mechanical frequency [S. Roundy, E. S. Leland, J. Baker, E. Carleton, E. Reilly, E. Laf, B. Otis, J. M. Rabacy, P. K. Wright, IEEE Pervasive Computing, January-March:28-35 (2005)]. The resonance fiequency based harvesting approach limits operation to a very narrow frequency band. Also, because most structural resonance frequencies are small (i.e., below 100 Hz), the amount of power that can be harvested per unit volume per device is limited because power is proportional to input frequency. It is, therefore, desirable to be able to convert a low range mechanical frequency to a higher resonant frequency, given that many piezoelectric materials and magnetostrictive materials are capable of operating at frequencies in the 10's of kHz. This would represent orders of magnitude increases in power harvested per unit of devices.

### BRIEF SUMMARY OF THE INVENTION

An objective of the present invention is to provide an approach to rectify a low mechanical frequency to a higher frequency mode. The present invention represents a significant advancement compared to prior energy harvesting designs. The current invention may utilize an inverse frequency rectification approach. The inverse frequency rectification converts a low frequency oscillation source, which may, for example, be from an ambient vibration, to a much higher frequency oscillation. This rectification allows substantially more power per unit mass to be harvested than previously possible. To date all the energy harvesters have relied on the relatively low ambient vibrations and have not used or proposed the feature of inverse frequency rectification. The addition of frequency rectifiers dramatically increases the power output per unit volume. The inverse frequency rectification approach can potentially generate power densities on the order of W/cm³ levels, two to three orders of magnitude larger than currently obtainable by conventional piezoelectric energy harvesters.

The rectified frequency may be applied to an electro-mechanical or magneto-mechanical material to convert the mechanical power into electrical power. By using an electro-mechanical material a voltage-based harvesting system may be obtained, while by using a magneto-mechanical material a current-based harvesting system may be obtained.

An energy harvesting apparatus according to an embodiment of the invention includes an inverse frequency rectifier structured to receive mechanical energy at a first frequency, and a solid state electromechanical transducer coupled to the inverse frequency rectifier to receive a force provided by the inverse frequency rectifier. The force, when provided by the inverse frequency rectifier, causes the solid state transducer to be subjected to a second frequency that is higher than the first frequency to thereby generate electrical power. A system according to embodiments of the invention may comprise the above-described apparatus, as well as an electrical device coupled to receive the electrical signal. Embodiments of the invention may also include methods of implementing the above-described apparatus.

### BRIEF DESCRIPTION OF THE DRAWINGS

Additional features of this invention are provided in the following detailed description of various embodiments of the invention with reference to the drawings. Furthermore, the above-discussed and other attendant advantages of the present invention will become better understood by reference to the detailed description when taken in conjunction with the accompanying drawings, in which:

FIG. 1 depicts a conventional resonant piezoelectric harvester operating schematic;

FIG. 2 depicts one embodiment of an inverse frequency rectification operating schematic with a rectifier;

FIG. 3 depicts a second embodiment of the present invention with an array of frequency rectifiers;

FIG. 4 illustrates amplitude-time characteristics of an ambient vibration source;

FIG. 5 illustrates amplitude-time characteristics of the prior art in which no rectifier is used, for example, as shown in FIG. 1;

FIG. 6 illustrates amplitude-time characteristics of an embodiment of the invention in which one rectifier is used, for example, as with the embodiment shown in FIG. 2;

FIG. 7 illustrates amplitude-time characteristics of an embodiment of the invention in which three series of rectifiers are used, for examples, as with the embodiment shown in FIG. 3; and

FIG. 8 illustrates a general system block diagram according to embodiments of the invention.

### DETAILED DESCRIPTION OF VARIOUS EMBODIMENTS

An inverse frequency rectification may be provided in accordance with embodiments of the present invention to generate higher resonant frequency vibration without changing the generator design for resonance-tuning. Given this, it may be advantageous to have a single design that operates effectively over a range of vibration frequencies. The following detailed description sets forth examples of embodiments of the current invention that are a few of the many considered possible for this invention, and as such, the description is regarded as disclosing representative examples. Other harvesting supports are not necessary for an understanding of the invention and are not illustrated. In other instances, well known features have not been described in detail so as to unnecessarily obscure the present invention. The figures illustrating various embodiments of the present invention are not drawn to scale.

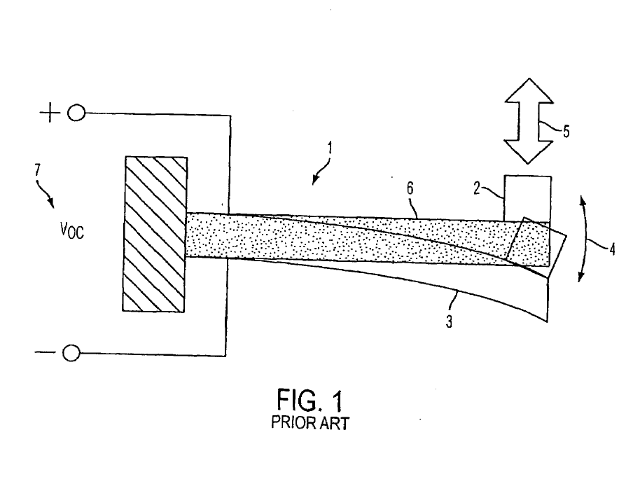

FIG. 1 shows an embodiment of a conventional piezoelectric generator. In FIG. 1, a resonant piezoelectric generator comprises a piezoelectric material generator 1 in the form of a clamped cantilever beam 6. A proof mass 2 is attached to the free end of the beam 6. The beam is excited by transverse vibrations. An ambient vibration source 5 causes the cantilever beam 6 to resonate at the frequency corresponding to the environrment's dominant mechanical frequency. As the figure shows, bending the beam 6 downward or upward during resonance mode 3 produces a repeated mechanical strain. By inducing a strain in a piezoelectric material, a voltage 7 is generated across the beam, and energy may be harvested from the system, for example, using electrical contacts (e.g., wire leads) coupled to the piezoelectric material. The amplitude of deformation is determined by the geometry, mass at the tip and material of the generator.

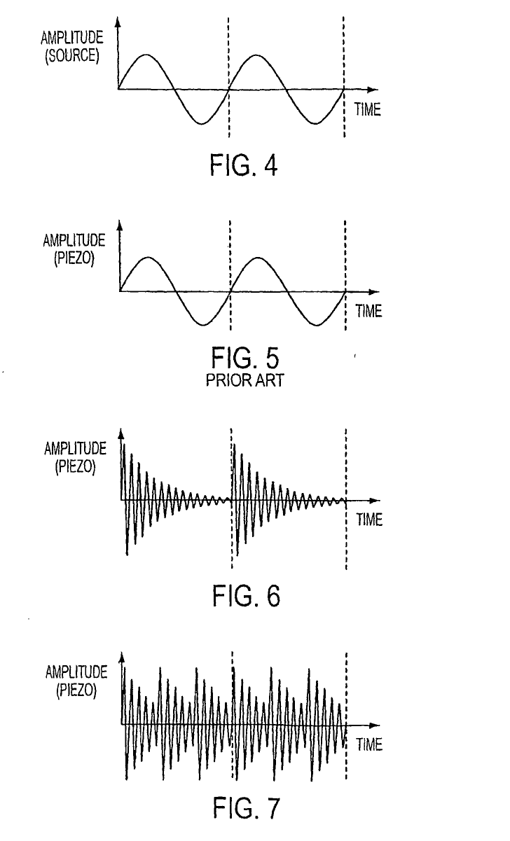

FIG. 4 shows the displacement amplitude waveform associated with the harmonic ambient driving force during two cycles. FIG. 5 shows the excited piezoelectric generator's displacement (or, equivalently, voltage) amplitude waveform. The generator resonates with small amplitude at the frequency corresponding to the driving frequency shown in FIG. 4.

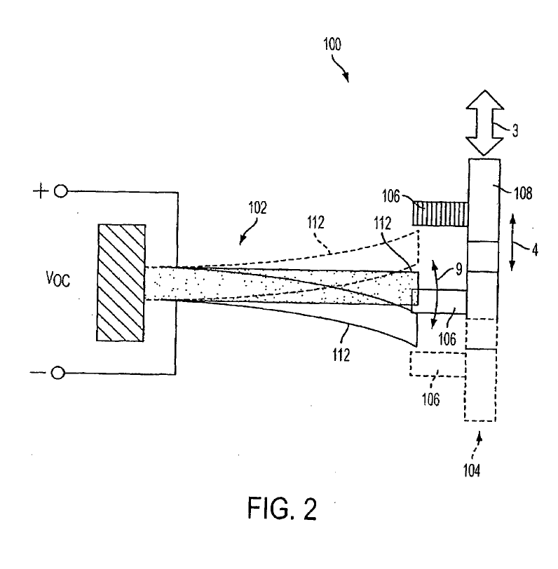

FIG. 2 illustrates a representative embodiment of an inverse frequency rectification device in accordance with the invention; “Frequency rectification” refers to the conversion of high frequency oscillation/movement to low frequency oscillation/movement; hence, “inverse frequency rectification” refers to the conversion of low frequency oscillation/movement to high frequency oscillation/movement. One operating mode of the invention may be in the form of a piezoelectric cantilever-based system as in the aforementioned conventional vibration-based harvester. The proposed inverse frequency rectification device 100 may be comprised of at least one energy generator 102 exhibiting strain induced electrical energy and a frequency rectifier 104 made of a rubber rectifier 106 attached to a metal bar 108. The general concepts of the invention are not limited to the particular materials and structures described in the current example. The rectifier 106 bends the beam 112 downward. The beam 112 released from rectifier 106 vibrates at the natural frequency of beam 112 with varying amplitude. The excited frequency is much higher than that of the conventional generator shown in FIG. 1. FIG. 6 shows an example of voltage amplitude waveform of the piezoelectric generator with a single rectifier, as shown in FIG. 2.

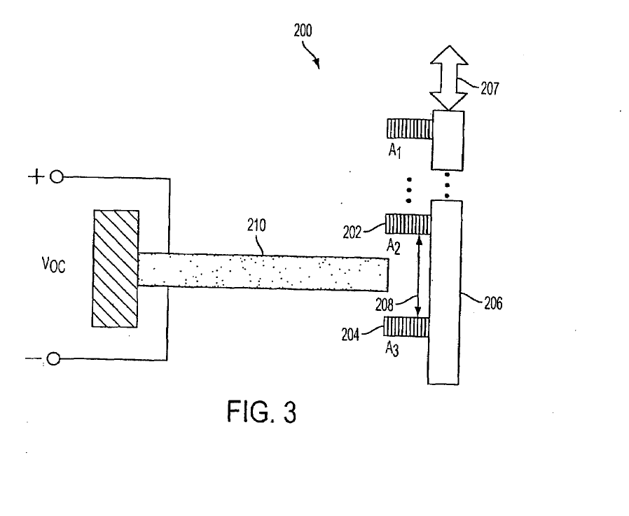

FIG. 3 illustrates a representative embodiment of an inverse frequency rectification device 200 with multiple rectifiers 202 and 204 attached to metal bar 206. The invention is not limited to the use of only metal bars 206 for the inverse frequency rectification device 200. Other materials and structures may be used without departing from the scope of the invention. As in FIG. 2, as the rectifiers 202 and 204 are moved in accordance with the resonance mode 207, each time a distance 208 between rectifiers 202 and 204 is traversed (in either direction), energy generator 210 is bent and released, resulting in the reinitiation of vibration of energy generator 210 each time it is bent and released by a rectifiers 202 and 204. As a result, improved energy output may be obtained. FIG. 7 shows an example of voltage amplitude waveform of the piezoelectric generator with multiple rectifiers, for example, three rectifiers in this case. Note that the number of such rectifiers 202, 204 is arbitrary, and the resulting voltage amplitude waveform may have a shape that correlates with the number of rectifiers 202, 204 (e.g., in terms of the number of excitation peaks). An inverse frequency rectifier may have one, two, three or a larger number of rectifiers, including a continuous non-discrete system, without departing from the scope of this invention.

As discussed above, the above embodiments are shown in the figures using an inverse frequency rectification scheme in which a bar or other surface having transversely mounted tooth-like rectifiers is vibrated such that the rectifiers cause a flexible, displaceable structure to repeatedly be excited into vibration. However, the invention is not intended to be thus limited. Rather the invention is intended to encompass any known or as yet to be discovered inverse frequency rectification method or device, circular, linear, or otherwise (for example, an alternative structure may use gears to achieve inverse frequency rectification in a circular fashion; another alternative structure may utilize a rack-and-pinion-based system to achieve a continuous non-discrete system).

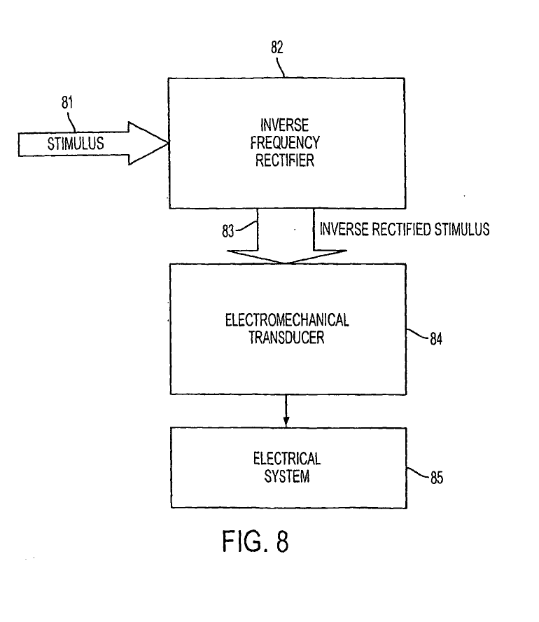

FIG. 8 illustrates a general block diagram of a system according to embodiments of the invention. In general, a mechanical stimulus 81 at a first frequency may be applied to an inverse frequency rectifier 82. In general, there may be multiple frequencies and/or a band of frequencies that excite the inverse frequency rectifier 82. The inverse frequency rectifier 82 outputs an inverse rectified stimulus 83 at a second frequency that excites an electromechanical transducer at a higher frequency than the first frequency. One should understand that the second frequency may be one of a spectrum of frequencies. The inverse rectified stimulus 83 may then be applied to an electromechanical transducer 84, which may be, for example (but is not limited to), a piezoelectric-based device, as discussed above, to convert the inverse rectified mechanical stimulus 83 to electrical energy. The electrical energy thus produced may be applied to an electrical system 85. As discussed above, electrical system 85 may include one or more storage devices (batteries, capacitors, etc.) and/or circuits to which the electrical energy may be directly applied.

A system like that of FIG. 8 may be deployed in many scenarios. Typical scenarios are those in which a low-power electrical system is to be powered in an environment where there is ambient mechanical stimulus (e.g., vibration). (Typical ambient mechanical frequencies that may excite an inverse frequency rectifier may be, for example about 0.1 Hz to 1,000 Hz while suitable solid state components may be selected from available electromechanical transducers that oscillate at about 100 Hz to about 1 GHz. However, these are just some examples. The general concepts of this invention are not limited to these particular parameters.) For example, remote sensing and/or communication devices may be deployed in such environments (e.g., mounted on machinery or other platforms that normally vibrate, are subjected to vibration, and/or otherwise move), and embodiments of the inventive system may be used to provide power to such devices without the use of batteries or wired power sources.

The invention has been described in detail with respect to various embodiments, and it will now be apparent from the foregoing to those skilled in the art that changes and modifications may be made without departing from the invention in its broader aspects, and the invention, therefore, as defined in the claims is intended to cover all such changes and modifications as fall within the true spirit of the invention.

We claim:

1. An energy harvesting apparatus, comprising:
an inverse frequency rectifier structured to receive mechanical energy at a first frequency; and
a solid state electromechanical transducer coupled to said inverse frequency rectifier to receive a force provided by said inverse frequency rectifier,
wherein said force when provided by said inverse frequency rectifier causes said solid state transducer to be subjected to a second frequency that is higher than said first frequency to thereby generate electrical power.

2. The apparatus according to claim 1, wherein said inverse frequency rectifier is structured to receive mechanical energy at a a band of frequencies that includes said first frequency.

3. The apparatus according to claim 1, wherein said force provided by said inverse frequency rectifier is a periodic force having a period substantially equal to said first frequency.

4. The apparatus according to claim 1, wherein said force provided by said inverse frequency rectifier is a periodic force having a period greater than said first frequency.

5. The apparatus according to claim 1, wherein said mechanical energy comprises ambient movement.

6. The apparatus according to claim 1, wherein said inverse frequency rectifier is of a linear type.

7. The apparatus according to claim 1, wherein said inverse frequency rectifier is of a circular type.

8. The apparatus according to claim 1, wherein said inverse frequency rectifier includes a rack-and-pinion structure.

9. The apparatus according to claim 1, wherein said solid state electromechanical transducer comprises a piezoelectric material.

10. The apparatus according to claim 1, wherein said solid state electromechanical transducer comprises at least one of an electrostrictive material and a magnetostrictive material.

11. The apparatus according to claim 1, further comprising:
an electrical storage device coupled to receive said electrical power.

12. The apparatus according to claim 11, wherein said electrical storage device comprises a battery.

13. The apparatus according to claim 11, wherein said electrical storage device comprises a capacitor.

14. An electrical system, comprising:
an energy harvesting apparatus, comprising:
an inverse frequency rectifier structured to receive mechanical energy at a first frequency; and
a solid state electromechanical transducer coupled to said inverse frequency rectifier to receive a force provided by said inverse frequency rectifier,
wherein said force when provided by said inverse frequency rectifier causes said solid state transducer to be subjected to a second frequency that is higher than said first frequency to thereby generate electrical power; and
an electrical device coupled to receive said electrical power generated by said energy harvesting apparatus.

15. The system according to claim 14, wherein said electrical device comprises a sensor.

16. The system according to claim 14, wherein said electrical device comprises a communication device.

17. A method of harvesting electrical energy from an environment, comprising:
providing a mechanical structure adapted to be excited into a periodic motion at a first frequency upon being exposed to said environment; and
coupling said mechanical stricture to a solid state component to cause said solid state component to be excited into a periodic motion by a second frequency that is higher than said first frequency,
wherein said solid state component is suitable to generate electrical power at said second frequency when excited through coupling to said mechanical structure.

18. The method according to claim 17, further comprising:
storing electrical energy produced by said solid state component.

19. The method according to claim 17, further comprising:
powering an electrical device with electrical energy produced by said solid state component.
